(19) United States
(12) Patent Application Publication
(10) Pub. No.: US 2025/0341457 A1
(43) Pub. Date: Nov. 6, 2025

(54) SYSTEMS AND METHODS TO REMOTELY OBTAIN PIPELINE POTENTIALS

(71) Applicant: GPT Industries, LLC, Wheat Ridge, CO (US)

(72) Inventors: Gabriel Gonzales, Las Cruces, NM (US); Nicholas Bander, Littleton, CO (US); Ian Kinnear, Arvada, CO (US); Aaron Alfano, Littleton, CO (US); Tim Hurley, Littleton, CO (US)

(21) Appl. No.: 18/864,705

(22) PCT Filed: May 9, 2023
(86) PCT No.: PCT/US2023/021566

§ 371 Date: Nov. 11, 2024

Related U.S. Application Data
(60) Provisional application No. 63/340,074, filed on May 10, 2022.

(51) Int. Cl. G01N 17/02; C23F 13/04; G01N 17/00; G01N 17/04; G01R 27/14

(52) U.S. Cl. CPC G01N 17/02; C23F 13/04; G01N 17/006; G01N 17/043; G01R 27/14; C23F 2213/32

(57) ABSTRACT

A system to measure potentials in a metal pipeline having isolation and cathodic protection is provided. The system is configured to measure the instant off (I-Off) potential of the protected metal pipeline. The system includes a first metal asset, such as a pipeline, electrically coupled to a cathodic protection element, such as a sacrificial metal. A switch is electrically coupled to the first metal asset, wherein the switch has an open position and a closed position. The monitoring device measures the I-Off potential when the switch is in the open position.

### CROSS-REFERENCE TO RELATED PATENT APPLICATIONS

The present application is related to U.S. patent application Ser. No. 17/584,165, filed Jan. 25, 2022, titled Methods and Apparatus for Remote Joint Isolation Monitoring, the disclosure of which is incorporated herein by reference as if set out in full and for all purposes.

### BACKGROUND

The technology of the present application relates to metal pipelines and, more particularly, to remotely measuring metal pipeline potentials as a way to evaluate, among other things, pipeline corrosion, and corrosion resistance or protection.

Transportation of media can take place via many means, including railcars, trucks, ships, and the like. However, a large portion of media around the world are transported via metal pipelines. The metal pipelines are typically steel.

The pipelines may be above ground, in which case they are typically raised off the ground, or they may be buried in the ground or soil, or they may be submerged in a body of water, which may be fresh or salt water. The pipelines are exposed in these environments to corrosive elements. Many pipelines, including steel pipelines, may be coated with a corrosion-resistant material to inhibit corrosion. But these pipelines are often in remote and difficult to maintain locations. Thus, over time, the coating may fail, exposing the metal of the pipe to corrosion, such as galvanic corrosion or simple rusting and oxidation.

Many pipelines include systems to mitigate or limit corrosion. The corrosion mitigation system may be, among other things, one or more cathodic protection systems to inhibit corrosion of the metal pipelines. Cathodic protection systems may include, among other things, a sacrificial metal. In the most basic terms, the cathodic protection system polarizes the pipe or protected structure (aka the asset) converting it into a cathode in equilibrium and the sacrificial metal corrodes rather than the pipeline metals. While effective, cathodic protection can fail as well due to extinction of the sacrificial metal or other failures, such as isolation method failure.

Conventional methods of monitoring cathodic protection and/or joint isolation are unsatisfactory. Thus, against this background, it would be desirable to provide improved systems and methods to remotely obtain pipeline potentials.

### SUMMARY

This Summary is provided to introduce, in a simplified form, a selection of concepts that are further described below in the Detailed Description. This Summary, and the foregoing Background, is not intended to identify key aspects or essential aspects of the claimed subject matter. Moreover, this Summary is not intended for use as an aid in determining the scope of the claimed subject matter.

In some aspects of the technology, a system is configured to measure the on potential of an asset, instant off (I-Off) potential, isolation, bond current via a shunt, and coupon testing of both native and I-Off of a metal asset is provided. The system may include a first metal asset, such as a pipeline, electrically coupled to a cathodic protection element, such as a sacrificial metal. A switch is electrically coupled to the first metal asset, wherein the switch has an open position and a closed position. The system also may include a metal coupon selectively, electrically coupled to the first metal asset via the switch. A potential monitoring device is electrically coupled to the metal coupon and the first metal asset such that the potential monitoring device measures the potential of the first metal asset with cathodic protection, wherein the potential monitoring device monitors the potential of the metal coupon and is configured to measure the I-Off potential when the switch is moved from the closed position where the metal coupon is electrically coupled to the first metal asset to the open position where the metal coupon is electrically isolated from the first metal asset.

In some embodiments, the first metal asset is a metal pipeline. And the metal coupon is formed from the same metal as the first metal asset and/or the same metal as the metal pipeline, which may be steel for any of the metals.

In the embodiments as outlined above, the system may include a transmitter, wherein the transmitter transmits the I-Off potential. The transmitter may be a cellular transmitter or a satellite transmitter, which is helpful for remote metal pipelines.

In the referenced embodiments above, the system may include a second metal asset and a shunt (or short) that electrically couples the first metal asset and the second metal asset. In certain aspects the shunt couples a first and second metal pipeline such that the second metal asset, or pipeline, is coupled to the cathodic protection element. In certain aspects, the potential monitoring device is configured to measure potential across the shunt.

In some aspects of the technology, a system is configured to measure a corrosion free or a native potential of a metal asset. The system includes a first metal asset electrically coupled to a cathodic protection element and a metal coupon located proximate to the first metal asset and electrically isolated from the first metal asset. A potential monitoring device is electrically coupled to the metal coupon and separately electrically coupled to the first metal asset. The potential monitoring device is configured to monitor the potential of the metal coupon and the potential of the first metal asset wherein the potential of the metal coupon is the corrosion free potential of the system.

In the embodiments described above, the first metal asset may be a buried pipeline and, in certain aspects, the metal asset or the buried pipeline is steel and the metal coupon is steel.

In the embodiments described above, the system may be configured for both measurement of the native potential and the I-Off potential.

These and other aspects of the present system and method will be apparent after consideration of the Detailed Description and Figures herein.

### DRAWINGS

Non-limiting and non-exhaustive embodiments of the present invention, including the preferred embodiment, are described with reference to the following figures, wherein like reference numerals refer to like parts throughout the various views unless otherwise specified.

FIG. 1 is a system diagram of a system showing a potential drop across an asset consistent with the technology of the present application.

FIG. 2 is a graph showing a measured potential across an asset over time consistent with the technology of the present application.

FIG. 3 shows an exemplary shunt between a first asset and a second asset consistent with the technology of the present application.

FIG. 4 shows an exemplary coupon with two leads consistent with the technology of the present application.

FIG. 5 shows an exemplary voltage/potential test station with multiple coupons consistent with the technology of the present application.

FIG. 6 is an exemplary flowchart of measuring a voltage/potential using the voltage/potential monitoring device of FIG. 7.

FIG. 7 is an exemplary flowchart expanding on the methodology of the exemplary flowchart of FIG. 6.

FIG. 8 shows the voltage/potential monitoring device coupled to a pipeline having cathodic protection consistent with the technology of the present application.

FIG. 9 is a functional block diagram of a device(s) on which the technology of the present application may be implemented.

### DETAILED DESCRIPTION

The technology of the present application will now be described more fully with reference to the accompanying figures, which form a part hereof and show, by way of illustration, specific exemplary embodiments. These embodiments are disclosed in sufficient detail to enable those skilled in the art to practice the technology of the present application. However, embodiments may be implemented in many different forms and should not be construed as being limited to the embodiments set forth herein. The following Detailed Description is, therefore, not to be taken in a limiting sense.

The technology of the present application is described with specific reference to metal pipes, specifically steel pipes, to transport media, such as, for example, oil, gas, water, or chemicals. However, the technology described herein may be used with applications other than those specifically described herein. For example, the technology of the present application may be applicable to power plant pipelines, refrigerant pipes, other media transport systems, or the like. Moreover, the technology of the present application will be described with relation to exemplary embodiments. The word “exemplary” is used herein to mean “serving as an example, instance, or illustration.” Any embodiment described herein as “exemplary” is not necessarily to be construed as preferred or advantageous over other embodiments. Additionally, unless specifically identified otherwise, all embodiments described herein should be considered exemplary.

Generally, one of the deficiencies of present isolation system monitoring is the type of parameters monitored. Typically, systems measure pipeline to soil potentials to determine whether cathodic protection is adequate and/or if isolation of the joint exists. The technology of the present application includes the ability to sense, transmit, and display isolation parameters, such as pipeline to soil potentials, but also senses, monitors, transmits, and displays instant-off (“I-Off”) potential, on potential, critical bond effectiveness, and coupon potentials alone (native potential) or with I-Offs (disengaged from cathodic protection).

An I-Off potential measurement measures the IR-Free potential of an asset, such as a pipe flange or joint. IR-Free potential is the potential measurement while removing the voltage drops in a system (i.e., V=IR). IR-Free potential refers to all the unknown resistances in the system being removed, allowing a true potential of the asset to be measured. In certain instances, measuring the potential of the asset, such as, for example, the metal pipeline, while cathodic protection is engaged (or on), which is referred to herein as operating potential or on potential, may introduce inaccurate potentials as the total system loss is not incorporated.

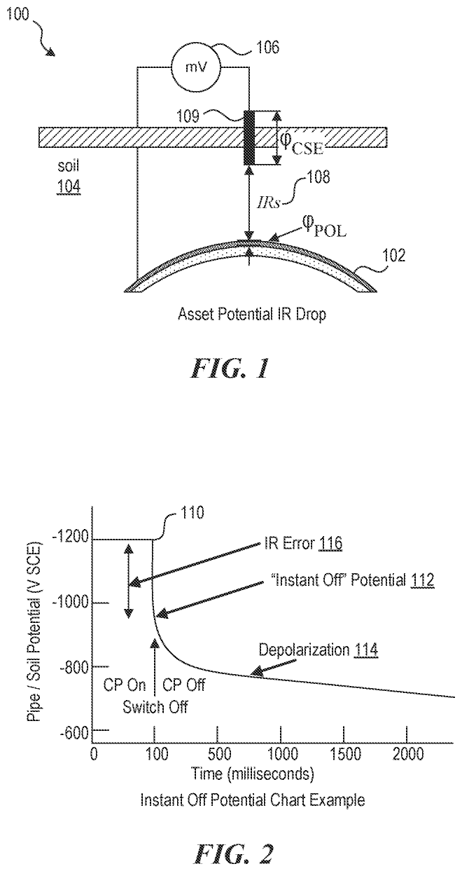

The I-Off potential is measured by interrupting the power to a DC power supply (rectifier). In the case of a pipeline, interrupting the rectifier corresponds to turning off the cathodic protection for the pipeline, which is isolating the sacrificial metal/anode. With reference to FIG. 1, an asset potential testing circuit 100 is shown. The asset potential testing circuit includes the asset 102 (or pipeline 102 in certain examples), which is shown buried in soil 104. The asset potential testing circuit 102 includes a voltage measurement source 106, which may include a voltage/potential monitoring device, a reference electrode 109, and a total system resistance 108. The voltage reading, taken by an analog meter 106, for example, for the system to determine the I-Off potential is shown by FIG. 2. FIG. 2 shows a potential between the soil and the pipeline over time. With the cathodic protection engaged (or on), the measured voltage is a steady state value 110, generally considered to be about −850 mVolts when in respect to a Copper-Copper Sulfate reference electrode, but could be other values. The steady state value 110 is commonly known as the “on potential”. The cathodic protection is interrupted at 100 msec, at which time the measured voltage drops to the I-Off potential 112, which is at the kick point when the voltage graph curves towards depolarization 114. The difference of the potential with cathodic protection, the steady state value 110, and the I-Off potential 112 is the IR error 116.

A critical bond potential relates to the metallic connections between adjacent buried structures that, if not connected, would allow detrimental corrosion to occur on the metal pipeline (also known herein as asset). In other words, the critical bond electrically joins two structures together, such as, for example, through an electrical short. Generally, as it relates to cathodic protection, a critical bond is used when the cathodic protection is being applied to a first asset and to a second asset through an electrical short to the first asset. For instance, the upstream pipeline may be coupled to a cathodic protection element, such as a sacrificial metal, but the downstream pipeline is not separately connected to a sacrificial metal. To protect the downstream pipeline using the upstream pipeline's cathodic protection element, a critical bond is established between the upstream pipeline and the downstream pipeline.

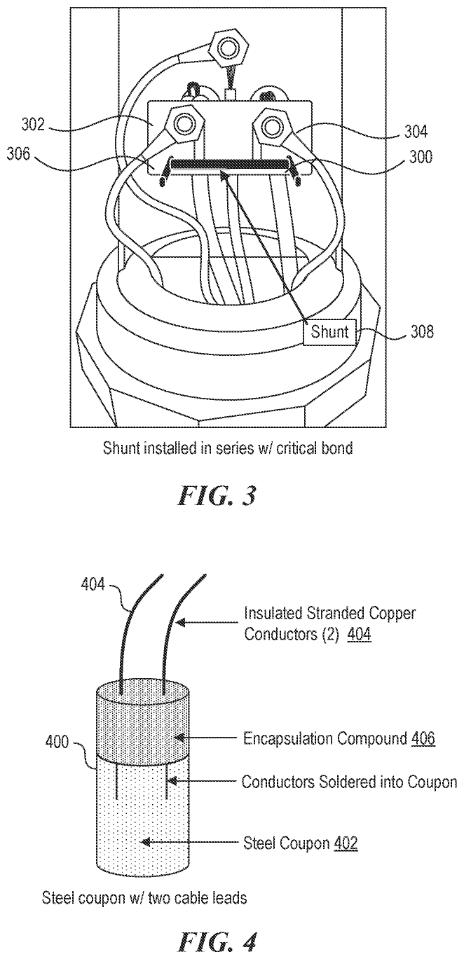

When a critical bond is established between a first asset and a second asset, such as the aforementioned upstream pipeline and downstream pipeline, a critical bond circuit includes an electrical connection that may include a shunt in series with the first and second assets. The shunt is a known, low impedance (or, more simply, a low resistance) element. In certain embodiments, the shunt may be considered an electrical short. FIG. 3 shows an exemplary critical bond circuit 300. The critical bond circuit includes the first asset 302, the upstream pipeline in this example, and the second asset 304, the downstream pipeline in this example. An electrical connection 306 is formed between the first asset 302 and the second asset 304. The electrical connection 306 includes a shunt 308, which may be integrated into the electrical connection 306. The shunt 308 allows for the determination of the potential (a.k.a. the critical bond potential) across the shunt 308. Because the resistance of the shunt 308 is known, and the potential across the shunt 308 is known, the current across the shunt is determinable using, for example, the formula V=IR.

A coupon is an element used in cathodic protection systems, but it has other uses as well. The coupon may be used to measure potentials in cathodic protection systems, along with other uses. The asset, such as a metal pipeline, may have a cathodic protection element electrically coupled to the asset. A coupon also may be electrically coupled to the metal pipeline. The coupon is formed of the same metal as the asset, or the same metal as the metal pipeline, which may be, for example, steel.

FIG. 4 shows a sample coupon 400 for a steel asset, such as a steel pipeline. The coupon 400 has a metal element 402, which is steel in this exemplary embodiment. The coupon 400 also includes one lead 404 or two leads 404, such as the two leads 404 shown in FIG. 4. The leads may be connected to the metal element 402 using an encapsulation compound 406 and by soldering the leads to the metal element 402. The coupon 400 has many uses for cathodic protection systems, but the present application uses the coupon 400 specifically for measurement of potentials, such as the aforementioned I-Off potential. Another useful potential is the native potential of the asset.

FIG. 4 shows the coupon 400 set up to measure the I-Off potential of the cathodic protection system discussed above. The metal element 402 is the same metal as the asset, which in this case is steel. A first of the two leads 404 is coupled to the asset, such as the upstream pipeline. Because the upstream pipeline is electrically coupled to a sacrificial metal, the coupon 400 is coupled to the sacrificial metal through the electrical connection. A second of the two leads 404 is coupled to a voltage monitor (not shown in FIG. 4). A switch (not specifically shown in FIG. 4) or the like would be used to open the electrical connection between the asset, or the upstream pipeline, and the coupon 400. The voltage monitor coupled to the second of the two leads 404 would measure the I-Off potential from the coupon after the switch was opened as shown by FIG. 2.

The native potential, which is sometimes referred to as free corrosion potential, is the potential of the coupon, or the protected asset, without cathodic protection applied. To measure the native potential, the coupon 400 is placed in an environment close to the asset being monitored. The coupon is not protected by a cathodic protection system although the asset, such as the upstream pipeline, is protected by the cathodic protection system.

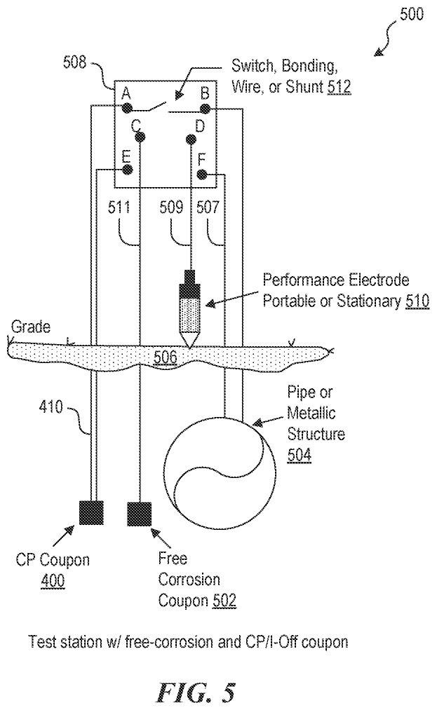

FIG. 5 shows a native potential circuit 500. The native potential circuit 500 includes a coupon 502 in the same environment as a first, or protected, asset 504, which is an upstream pipeline in the present example. In other words the coupon 502 is located proximate the asset 504. As shown, the asset 504 is buried in the ground 506 and so the coupon 502 also is buried proximate the location of the asset 504. A voltage monitoring device 508 includes a first connection 507 to the first asset 504 and a connection 509 to a reference electrode 510, which may be used for pipeline to soil potential readings as discussed in related U.S. patent application Ser. No. 17/584,165, which is incorporated herein by reference as if set out in full. The voltage monitoring device 508 includes a third connection 511 to the coupon 502. The coupon 502 is electrically isolated from the asset 504. For reference, FIG. 5 also shows the I-Off potential circuit discussed above. The same voltage monitoring device 508 may be used for the native potential and the I-Off potential although separate devices also may be used. The I-Off potential circuit 410, shown in FIG. 5, has the I-Off coupon 400 coupled to the first, protected, asset 504 through a switch 512 in the voltage monitoring device 508. To measure the I-Off potential, the switch 512 of circuit 410 is opened (as shown) to remove the cathodic protection from coupon 400.

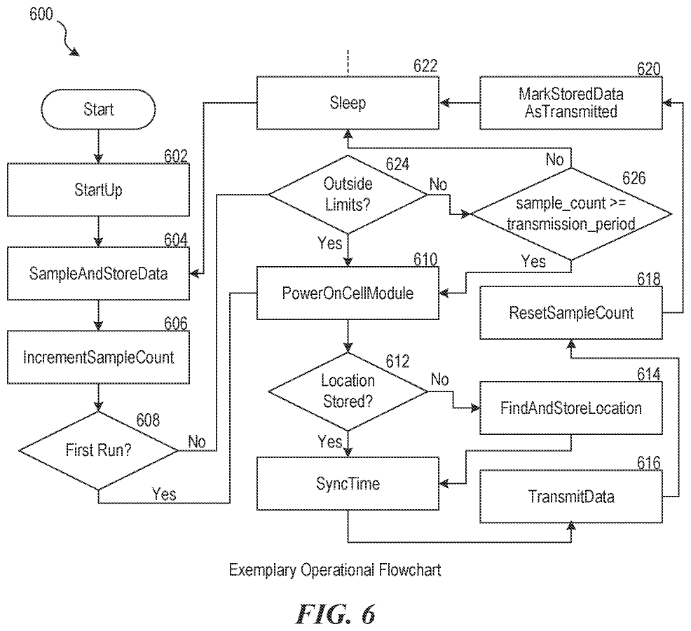

Obtaining the pipeline potentials discussed is difficult at remote locations. Also, because the locations are remote, providing power to the various pipeline locations is difficult. Moreover, the voltage monitoring device, switch, and other functional components of the system require power that should last a significant amount of time. To facilitate the remote gathering and transmission of the obtained pipeline potentials, FIG. 6 shows an exemplary operational flowchart 600. The operation of the system begins with a startup of the remote voltage/potential monitoring device, step 602. The remote voltage monitoring device generally will be in sleep mode, such as, a no power or low power mode, to reduce the overall power signature. Thus, the startup signal, which may be generated locally, powers on the processor and other parts of the voltage monitoring device. The no/low power mode may include the voltage monitoring device not monitoring the voltages or potentials, the switch in the default position, and a transmitter (described below) off among other features that may be off in the no/low power mode. Once started up, the voltage monitoring device samples the potentials at a known sample rate and stores the data, step 604. Next, sample count is incremented, step 606. The system next determines if the sampled and stored data from step 604 was a first data set of sampled and stored data, step 608. If the sampled and stored data is the first data set, the processor turns on the transmitter, step 610. As shown, the transmitter may be a transmitter that transmits on the cellular network. Other transmitters include IR transmitters, satellite transmitters, WiFi transmitters, LoRa transmitters, Sigfox transmitters, and the like. The processor next determines if the location of the voltage monitoring device is known, step 612. If the location is not known, the processor determines and stores the location of the voltage monitoring device, step 614. The location of the voltage monitoring device may be determined using the global positioning satellites or other means. If it is determined the location of the voltage monitoring device is stored, or after the location of the device is stored at step 614, the processor causes the transmitter to transmit the data to a central location, such as a network or system operation center, step 616. Once the complete run is transmitted, step 616, the sample counter is reset, step 618, the locally stored data is marked as transmitted, step 620, and the device is put back to sleep, step 622, which is no/low power mode. The sleep or no/low power mode may simply be turning the transmitter off.

With reference still to FIG. 6, if the system, based on the sample count total, has not completed a run of data, the processor next determines whether the sampled data is outside of a limit, step 624. The limits may be voltage thresholds that show failures or failing modes of operation, such as, for example, if a potential being measured crosses a threshold. If the sampled data is not outside a threshold value, the processor determines if the sample count is greater than or equal to a transmission count, step 626. Equaling or exceeding the sample count means, generally, that the set number of sample reads have been taken and stored. If it is determined that the sample count has not been reached, the processor enters sleep (or no/low power) mode, step 622, and returns to the startup step 602 when the next sample data is to be taken. If it is determined at step 624 that the sampled data is outside a limit, which may be an alert limit (failing) or an alarm limit (failed), the processor turns on the transmitter, step 610, and follows steps 610 to 622. Returning to step 626, if the processor determines the sample count has been met or exceeded, the processor turns on the transmitter, step 610, and follows steps 610-622.

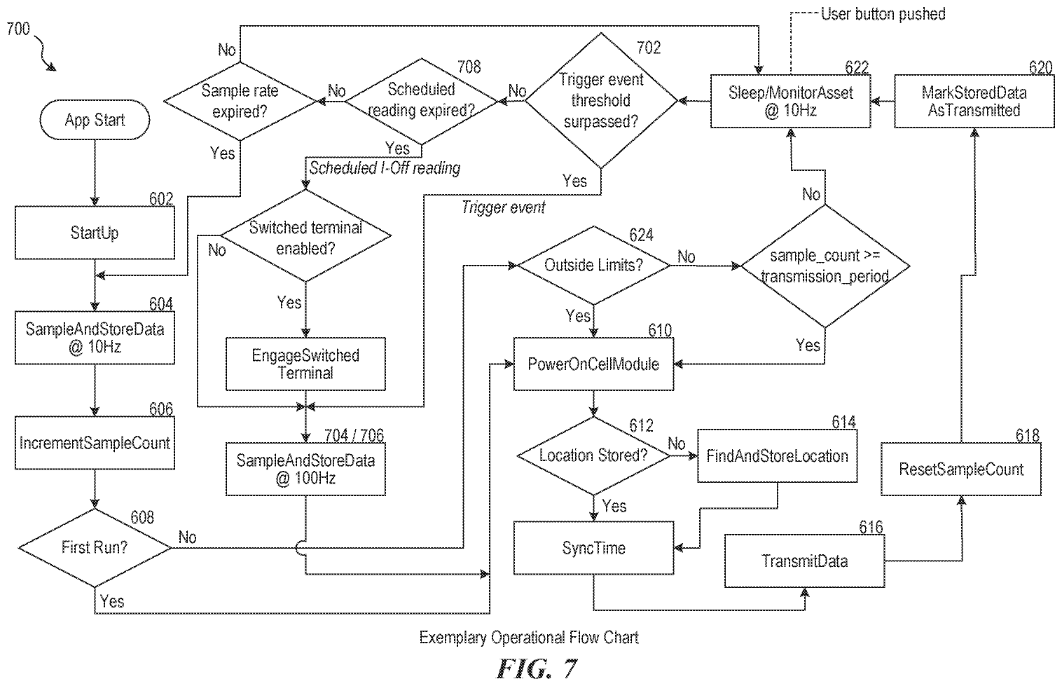

FIG. 7 shows an exemplary operational flowchart 700 for a potential monitoring device consistent with the technology of the present application. Flowchart 700 is similar to flowchart 600 with similar steps 602-626. Operational flowchart 700 includes a set monitoring of a potential, similar to flowchart 600, but also includes monitoring a potential (or potentials) continuously for specific events, termed triggers. For example, at step 626, the potential monitoring device enters a low power mode. This may turn off the transmitter, which is a larger power-using module, but leave the voltage monitoring device operating. The voltage monitoring device processor would determine, on a continuous basis, whether a monitored potential crosses a threshold, step 702. If it is determined that a threshold was crossed, the processor would set a potential monitoring sample rate, step 704. The sample rate may increase for an alert or an alarm condition, such as, for example, increasing the sample rate from about a sample every 10 Hz to a sample every 100 Hz or even higher frequency sampling. Next the processor samples and stores the data at the set sample rate, step 706. After sampling the required potentials from the triggering event, the processor would turn on the transmitter, step 610, and follow steps 610-622.

Also, if the voltage/potential monitoring device is programmed to measure the I-Off potential, the I-Off potential is generally a scheduled data point reading, which schedule is established by the user using a dashboard or other interface. Thus, while generally in sleep or no/low power mode, the processor at scheduled intervals determines whether a scheduled reading for I-Off potential is due, step 708. If the processor determines the scheduled reading for I-Off potential is due, the switch, such as switch 512 above or switch 778 below, is enabled or powered such that it can open and close. The process 700 next determines whether the switch is enabled, step 710. If it is determined the switch is enabled, the switch is engaged at step 712. Engaging the switch causes the switch to open and disengage the cathodic protection from a coupon, for example, allowing the I-Off potential to be sensed from the coupon. The switch may in fact be cycled open and closed a plurality of times for the reading process. In certain embodiments, the switch may be opened to interrupt the cathodic protection to the protected asset rather than to a coupon. If it is determined the switch is not enable, the switch remains in sleep or low power mode, which is closed. The I-Off sample rate is set to the I-Off sample frequency and the data is sampled and stored, steps 704/706. As mentioned above, to measure the I-Off potential, the coupon will be disconnected from the sacrificial anode by opening the switch in the I-Off circuit, such as is shown in I-Off circuit 410 above. Once the I-Off sample data is taken, the processor turns the transmitter on, step 610, and follows steps 610-622, and the switch would be closed. If it is determined that the schedule data reading does not need to occur, or the selected sampling (trigger event or I-Off) has expired, the processor returns to sleep until the next regular potential sample is to be taken, step 712.

System settings for the processor and voltage/potential monitoring device described above may generally be set based on the system parameters by those skilled in the art on reading this disclosure. The system has been found to work in a satisfactory way when set as follows for a system having two assets, such as an upstream and a downstream metal pipeline, generally referred to as asset A and asset B, as shown in table 1 below. Some of the readings below relate to information disclosed in related U.S. patent application Ser. No. 17/584,165, filed Jan. 25, 2022, disclosed as related above and incorporated herein by reference as if set out in full.

| | | | Default |
|---|---|---|---|
| System Parameter | Description | Units | Value |
| Sample rate | How frequently the system wakes up to | Seconds | 14400 |
| | read new data | | |
| Transmission period | How frequently the system initiates a | None | 6 |
| | cellular data transmission expressed | | |
| | as multiples of samples (e.g. for a sample | | |
| | rate of 4 hours and a transmission period | | |
| | of 6, the system would transmit every 24 | | |
| | hours) | | |
| Asset A protection high limit | Highest allowable asset protection voltage | Volts | −0.85 |
| Asset A protection low limit | Lowest allowable asset protection voltage | Volts | −10.0 |
| Asset A protection high enable | Enable asset protection voltage high limit | Boolean | 1 |
| Asset A protection low enable | Enable asset protection voltage low limit | Boolean | 1 |
| Asset B protection high limit | Highest allowable asset protection voltage | Volts | −0.85 |
| Asset B protection low limit | Lowest allowable asset protection voltage | Volts | −10.0 |
| Asset B protection high enable | Enable asset protection voltage high limit | Boolean | 1 |
| Asset B protection low enable | Enable asset protection voltage low limit | Boolean | 1 |
| Asset isolation high limit | Highest allowable asset isolation voltage | Volts | 10.0 |
| Asset isolation low limit | Lowest allowable asset isolation voltage | Volts | 0.1 |
| Asset isolation high enable | Enable asset isolation voltage high limit | Boolean | 1 |
| Asset isolation low enable | Enable asset isolation voltage low limit | Boolean | 1 |
| Scheduled reading | The set schedule for the unit to take | TBD | TBD |
| | readings for I-Off potentials | | |
| Scheduled reading length of | Amount of time that readings are taken for | Seconds | 60 |
| time | a scheduled reading | | |
| Scheduled reading enable | Enable scheduled readings | Boolean | 0 |
| Asset A trigger event threshold | Highest allowable change in potential | Volts | 0.100 |
| Asset A trigger event enable | Enable trigger event | Boolean | 1 |
| Asset B trigger event threshold | Highest allowable change in potential | Volts | 0.100 |
| Asset B trigger event enable | Enable trigger event | Boolean | 0 |
| Trigger event length of time | Amount of time that readings are taken in a | Seconds | 60 |
| | trigger event | | |
| Critical bond voltage high limit | Highest allowable critical bond voltage | Volts | 0.5 |
| Critical bond voltage low limit | Lowest allowable critical bond voltage | Volts | −0.5 |
| Critical bond high enabled | Enable critical bond voltage high limit | Boolean | 0 |
| Critical bond low enabled | Enable critical bond voltage low limit | Boolean | 0 |
| Shunt Size | Shunt size | Ohms | 0.001 |

Including all updates shown in Table 2: Phase 1 Updates to System Parameters

| | | | |
|---|---|---|---|
| Coupon protection high limit | Highest allowable asset protection voltage | Volts | −0.85 |
| Coupon protection low limit | Lowest allowable asset protection voltage | Volts | −10.0 |
| Coupon protection high enable | Enable asset protection voltage high limit | Boolean | 1 |
| Coupon protection low enable | Enable asset protection voltage low limit | Boolean | 1 |
| Coupon trigger event threshold | Highest allowable change in potential | Volts | 0.100 |
| Coupon trigger event enable | Enable trigger event | Boolean | 0 |
| Switched Terminal time | The set time that the switched terminal | Seconds | 5 |
| | repeatedly opens during a scheduled | | |
| | reading to get I-Off potentials of the coupon | | |
| Switched terminal enable | Enable the switch to turn on at set time | Boolean | 1 |

Note that the values herein are exemplary and not limiting.

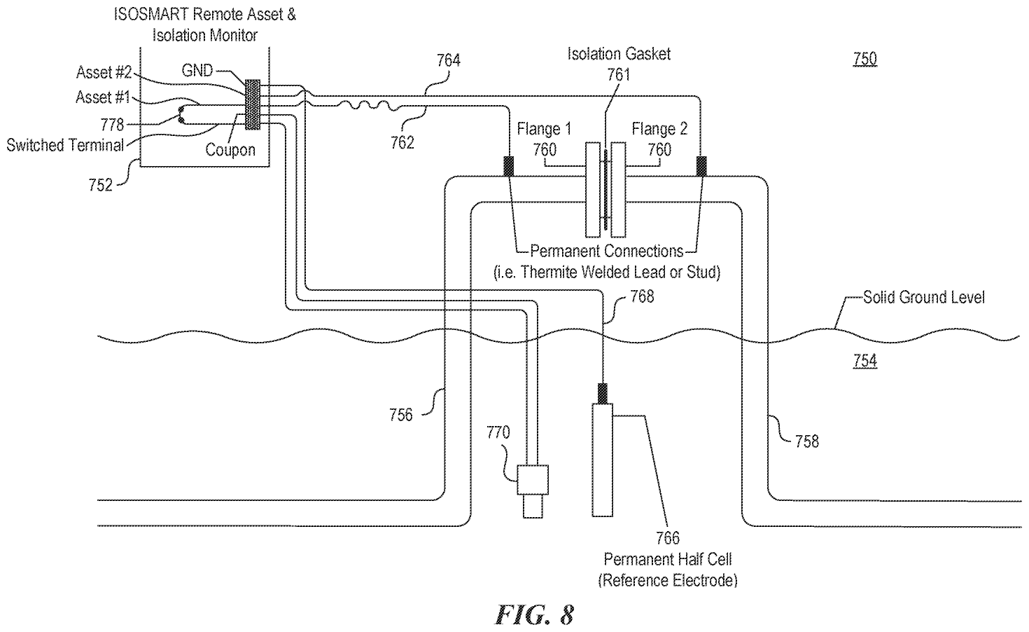

FIG. 8 shows a sample pipeline system 750 with a voltage/potential monitoring device 752. The pipeline system 750 is buried in the ground 754. The pipeline system 750 includes an upstream pipeline 756 and a downstream pipeline 758 coupled by a pair of opposed flanges 760 with an isolation gasket 761 between the sealing face of the opposed flanges 760. The voltage/potential monitoring device 752 has an upstream lead 762 coupling the upstream pipeline/protected asset (asset 1) to the voltage monitoring device 752 and a downstream lead 764 coupling the downstream/unprotected asset (asset 2) to the voltage monitoring device 752. The upstream lead 762 and the downstream lead 764 should be configured to have the same impedance. A reference electrode 766 is coupled to the voltage monitoring device 752 via a reference lead 768, which is further explained in U.S. patent application Ser. No. 17/584,165. A coupon 770 is coupled to the voltage monitoring device 752 via two coupon leads 772 and 774. The first lead couples the coupon to the upstream pipeline 756, which couples the coupon 772 to the cathodic protection element, and the sacrificial anode. When an I-Off potential reading is to be taken by the voltage monitoring device, a switch 778 is opened in the voltage monitoring device 752 to disconnect the coupon 770 from the sacrificial node to allow the I-Off potential to be read from the coupon 770.

As can now be appreciated on reading the present application, with a coupon coupled to the voltage monitoring device, the system will be able to measure the native potential of the upstream pipeline (also known as the protected asset, first asset, or asset A) if the coupon is formed from the same metal as the pipeline. Also, if the coupon has a second lead, it is possible to measure the I-Off potential by opening the switch to disconnect the coupon from the cathodic protection. Similarly, the system may measure the shunt voltage by measuring, for example, the voltage difference between the asset 1 input and the reference electrode input on the monitoring device.

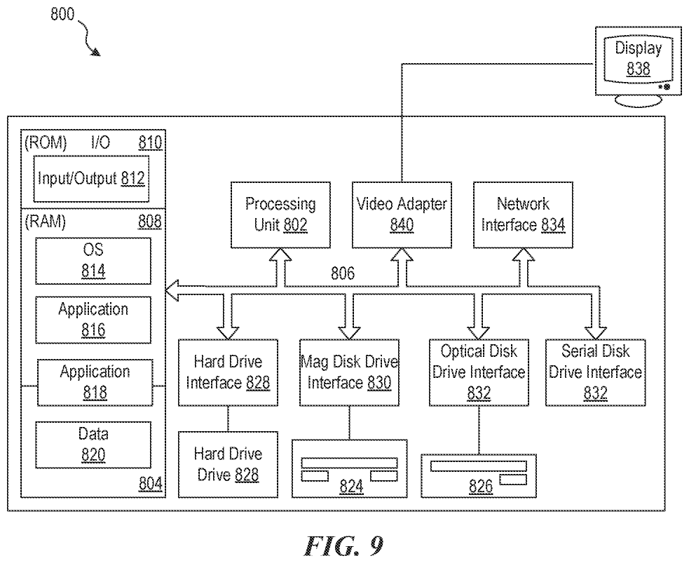

Referring now to FIG. 9, a functional block diagram of a typical client device 800 for the technology of the present application is provided. Client device 800 is shown as a single, contained unit, such as, for example, a desktop, laptop, handheld device, or mobile processor, but client device 800 may comprise portions that are remote and connectable via network connections such as via a local area network (LAN), a wide area network (WAN), a wireless LAN (WLAN), a WiFi network, the Internet, LoraWAN, Sigfox or the like. Generally, client device 800 includes a processor 802, a system memory 804, and a system bus 806. System bus 806 couples the various system components and allows data and control signals to be exchanged between the components. System bus 806 could operate on any number of conventional bus protocols. System memory 804 generally comprises both a random access memory (RAM) 808 and a read only memory (ROM) 810. ROM 810 generally stores a basic operating information system such as a basic input/output system (BIOS) 812. RAM 808 often contains the basic operating system (OS) 814, application software 816 and 818, and data 820. System memory 804 contains the code for executing the functions and processing the data as described herein to allow the present technology of the present application to function as described. Client device 800 generally includes one or more of a hard disk drive 822 (which also includes flash drives, solid state drives, etc., as well as other volatile and non-volatile memory configurations), a magnetic disk drive 824, or an optical disk drive 826. The drives also may include zip drives and other portable devices with memory capability. The drives are connected to the system bus 806 via a hard disk drive interface 828, a magnetic disk drive interface 830, and an optical disk drive interface 832, etc. Application modules and data may be stored on a disk, such as, for example, a hard disk installed in the hard disk drive (not shown). Client device 800 has a network connection 834 to connect to a LAN, a wireless network, an Ethernet, the Internet, or the like, as well as one or more serial port interfaces 836 to connect to peripherals, such as a mouse, keyboard, modem, or printer. Client device 800 also may have USB ports or wireless components, not shown. Typically, client device 800 has a display or monitor 838 connected to system bus 806 through an appropriate interface, such as a video adapter 840. Monitor 838 may be used as an input mechanism using a touch screen, a light pen, or the like. On reading this disclosure, those of skill in the art will recognize that many of the components discussed as separate units may be combined into one unit and an individual unit may be split into several different units. Further, the various functions could be contained in one personal computer or spread over several networked personal computers. The identified components may be upgraded and replaced as associated technology improves and advances are made in computing technology.

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention. The above identified components and modules may be superseded by new technologies as advancements to computer technology continue.

The various illustrative logical blocks, modules, and circuits described in connection with the embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

Although the technology has been described in language that is specific to certain structures and materials, it is to be understood that the invention defined in the appended claims is not necessarily limited to the specific structures and materials described. Rather, the specific aspects are described as forms of implementing the claimed invention. Because many embodiments of the invention can be practiced without departing from the spirit and scope of the invention, the invention resides in the claims hereinafter appended. Unless otherwise indicated, all numbers or expressions, such as those expressing dimensions, physical characteristics, etc., used in the specification (other than the claims) are understood as modified in all instances by the term “approximately.” At the very least, and not as an attempt to limit the application of the doctrine of equivalents to the claims, each numerical parameter recited in the specification or claims which is modified by the term “approximately” should at least be construed in light of the number of recited significant digits and by applying ordinary rounding techniques. Moreover, all ranges disclosed herein are to be understood to encompass and provide support for claims that recite any and all subranges or any and all individual values subsumed therein. For example, a stated range of 1 to 10 should be considered to include and provide support for claims that recite any and all subranges or individual values that are between and/or inclusive of the minimum value of 1 and the maximum value of 10; that is, all subranges beginning with a minimum value of 1 or more and ending with a maximum value of 10 or less (e.g., 5.5 to 10, 2.34 to 3.56, and so forth) or any values from 1 to 10 (e.g., 3, 5.8, 9.9994, and so forth).

What is claimed is:

1. A system configured to measure the on potential, instant off (I-Off) potential, isolation, bond current via a shunt, and coupon testing of both native and I-Off, comprising:
a first metal asset electrically coupled to a cathodic protection element;
a switch electrically coupled to the first metal asset wherein the switch has an open position and a closed position;
a metal coupon selectively, electrically coupled to the first metal asset via the switch; and
a potential monitoring device electrically coupled to the metal coupon and the first metal asset such that the potential monitoring device measures the potential of the first metal asset with cathodic protection, wherein
the potential monitoring device also monitors the potential of the metal coupon and is configured to measure the I-Off potential when the switch is moved from the closed position where the metal coupon is electrically coupled to the first metal asset to the open position where the metal coupon is electrically isolated from the first metal asset.

2. The system of claim 1 wherein the first metal asset is a metal pipeline.

3. The system of claim 2 wherein the first metal asset and the metal coupon are formed from the same metal.

4. The system of claim 1 comprising a transmitter wherein the transmitter transmits an on potential, the I-Off potential, isolation, bond current via shunt, and coupon potential.

5. The system of claim 4 wherein the transmitter is selected from the group of transmitters consisting of: a cellular transmitter, an IR transmitter, a satellite transmitter, a WiFi transmitter, a LoRa transmitter, a Sigfox transmitter, or a combination thereof.

6. The system of claim 1 comprising a second metal asset and a shunt that electrically couples the second metal asset to the first metal asset.

7. The system of claim 2 comprising a second metal pipeline and a shunt that electrically couples the second metal pipeline to the metal pipeline such that the second metal pipeline is coupled to the cathodic protection element.

8. The system of claim 6 wherein the potential monitoring device measures the potential across the shunt.

9. A system configured to measure a corrosion free or a native potential of a metal asset, comprising:
a first metal asset electrically coupled to a cathodic protection element;
a metal coupon located proximate to the first metal asset and electrically isolated from the first metal asset; and
a potential monitoring device electrically coupled to the metal coupon and separately electrically coupled to the first metal asset, wherein
the potential monitoring device monitors the potential of the metal coupon and the potential of the first metal asset,
wherein the potential of the metal coupon is the corrosion free potential of the system.

10. The system of claim 9 wherein the first metal asset is a buried pipeline.

11. The system of claim 10 wherein the buried pipeline and the metal coupon are made from the same metal.

12. A system configured to measure the instant off (I-Off) potential and native potential of a metal asset, comprising:
a first metal asset electrically coupled to a cathodic protection element;
a switch electrically coupled to the first metal asset wherein the switch has an open position and a closed position;
a first metal coupon selectively, electrically coupled to the first metal asset via the switch;
a potential monitoring device electrically coupled to the first metal coupon and the first metal asset such that the potential monitoring device measures the potential of the first metal asset with cathodic protection; and
a second metal coupon located proximate to the first metal asset, wherein the second metal coupon is electrically isolated from the first metal asset and electrically coupled to the potential monitoring device, wherein
the potential monitoring device monitors the native potential of the second metal coupon that is the native potential, and wherein
the potential monitoring device monitors the potential of the first metal coupon and is configured to measure the I-Off potential when the switch is moved from the closed position where the first metal coupon is electrically coupled to the first metal asset to the open position where the first metal coupon is electrically isolated from the first metal asset.

13. The system of claim 12 wherein the first metal asset, the first metal coupon, and the second metal coupon are made of the same material.

14. The system of claim 12 comprising a second metal asset electrically coupled to the first metal asset via a shunt.
